(19) United States
(12) Patent Application Publication
(10) Pub. No.: US 2024/0380353 A1
(43) Pub. Date: Nov. 14, 2024

(54) METHOD AND MACHINE CONTROLLER FOR MONITORING THE TEMPERATURE OF AN ELECTROMECHANICAL MACHINE

(71) Applicant: Siemens Aktiengesellschaft, München (DE)

(72) Inventors: Vincent Malik, München (DE); Mohamed Khalil, München (DE); Christian Andreas Wolf Pozzo, Zirndorf (DE); Benjamin Amschler, Heinersreuth (DE); Meinhard Paffrath, Feldkirchen (DE)

(21) Appl. No.: 18/565,771

(22) PCT Filed: May 20, 2022
(86) PCT No.: PCT/EP2022/063760

§ 371 Date: Nov. 30, 2023

(30) Foreign Application Priority Data
Jun. 16, 2021 (EP) 21179858.2

(51) Int. Cl. H02P 29/60; G01R 31/34; H02P 23/14

(52) U.S. Cl. CPC H02P 29/60; G01R 31/343; H02P 23/14

(57) ABSTRACT

In order to monitor the temperature of an electromechanical machine using electrical operating data of the machine, structural data concerning a geometry, a thermal conductivity and an electrical conductivity of elements of the machine is imported. Using the structural data and the electrical operating data, electrical energy losses in the machine are continuously simulated in a spatially resolved manner by means of an electrical simulation model of the machine. Furthermore, a temperature distribution in the machine is continuously simulated by means of a thermal simulation model of the machine using the structural data and the simulated electrical energy losses. In accordance with the simulated temperature distribution, a temperature value is then determined for a component of the machine and output in order to monitor its temperature.

### CROSS-REFERENCE TO RELATED APPLICATIONS

This application claims priority to PCT Application No. PCT/EP2022/063760, having a filing date of May 20, 2022, which claims priority to EP application Ser. No. 21/179,858.2, having a filing date of Jun. 16, 2021, the entire contents both of which are hereby incorporated by reference.

### FIELD OF TECHNOLOGY

The following relates to a method and machine controller for monitoring the temperature of an electromechanical machine.

### BACKGROUND

The operation of electromechanical machines, such as electric motors, in many cases requires monitoring the temperature of critical machine components, particularly in the higher power range. However, the temperatures of many machine components are difficult or impossible to measure directly. Installing temperature sensors on a rotor of a motor and transmitting sensor signals from there to a monitoring device is usually very technically complex.

However, in order to at least obtain estimates of expected operating temperatures, historical machine operating data are often used. For this purpose, however, large amounts of historical operating data are usually required for the machine in question, covering a wide range of operating conditions.

It is also known to evaluate measured values from temperature sensors that are installed at easily accessible points on the machine to be monitored. These measured values can then be used to draw conclusions about the temperatures of less accessible machine components using physical simulation models.

### SUMMARY

An aspect relates to provide a method and a machine controller for monitoring the temperature of an electromechanical machine, which allow more efficient and/or less complex temperature monitoring.

To monitor the temperature of an electromechanical machine on the basis of electrical operating data of the machine, structural data on geometry, thermal conductivity and electrical conductivity of elements of the machine are imported. Based on the structural data and the electrical operating data, electrical energy losses in the machine are continuously simulated in a spatially resolved manner using an electrical simulation model of the machine. Furthermore, based on the structural data and the simulated electrical energy losses, a temperature distribution in the machine is continuously simulated using a thermal simulation model of the machine. According to the simulated temperature distribution, a temperature value is then determined for a component of the machine and output for monitoring the temperature thereof.

A machine controller, a computer program product (non-transitory computer readable storage medium having instructions, which when executed by a processor, perform actions) and wherein the non-transitory computer readable storage medium is a non-volatile computer-readable storage medium are provided for executing the method according to embodiments of the invention.

The method according to embodiments of the invention as well as the machine controller according to embodiments of the invention can be executed or implemented, for example, by means of one or more computers, processors, application-specific integrated circuits (ASIC), digital signal processors (DSP) and/or so-called field-programmable gate arrays (FPGA).

One particular advantage of embodiments of the invention is that temperatures of machine components can be determined using operating data that are often already available in a machine controller. The installation of temperature sensors on or in the machine itself is therefore no longer necessary in many cases. In addition, the simulations can also be used to determine and/or monitor temperatures for machine components that are difficult to access, particularly inside the machine.

According to an advantageous embodiment of the invention, mechanical energy losses in the machine can be simulated in a spatially resolved manner using the structural data and mechanical operating data of the machine by means of a mechanical simulation model of the machine. The simulation of the temperature distribution can then be carried out using the simulated mechanical energy losses. In particular, the mechanical simulation model can simulate friction losses, e.g., in the machine's axle bearings. For this purpose, the structural data can include friction coefficients for the machine elements affected by friction losses.

Furthermore, the mechanical operating data can quantify a rotational speed, a torque, a speed of movement and/or an exerted force of the machine or a component thereof. Furthermore, the electrical operating data can in particular quantify an operating current and/or an operating voltage of the machine or a component thereof.

The aforementioned operating data are already available in many machine controllers, so that often no additional installations on or in the machine to be monitored are required for monitoring the temperature of the machine.

According to an advantageous development of embodiments of the invention, structural data on the electrical conductivity and/or the thermal conductivity of the machine elements can be modified depending on the simulated temperature distribution. A simulation of the electrical energy losses and/or the temperature distribution can then be carried out using the modified structural data. In particular, this allows a temperature dependence of electrical resistances to be taken into account in a simulation of electrical energy losses and/or a temperature dependence of thermal conductivity to be taken into account in a simulation of the temperature distribution. In this way, simulation accuracy can usually be significantly increased.

Furthermore, depending on the temperature value determined, the machine can be regulated down, information about optimized operation of the machine can be output and/or a cooling device can be activated. In many cases, the above measures can significantly reduce wear on the machine and/or increase its service life.

According to an advantageous embodiment of the invention, at least one of the simulations can be carried out using a data-driven surrogate model. In particular, an artificial neural network or another machine learning model can be used as a surrogate model. A respective surrogate model can be trained beforehand, e.g., by means of a physical simulation model, to predict its simulation results. Using a respective trained surrogate model, a respective simulation can then generally be carried out, in particular in real time, with considerably less computing effort.

According to a further advantageous embodiment of the invention, a position of a respective machine component can be determined in each case for a plurality of predetermined machine components on the basis of the structural data. A respective component-specific temperature value can then be output based on the respectively determined position and the temperature distribution. In this way, several critical machine components, e.g., a rotor, a stator, a winding, an axle bearing and/or insulation of an electric motor can be monitored individually.

According to a further advantageous development of embodiments of the invention, a temperature of the machine can be measured at a measuring point. The simulated temperature distribution can be used to determine a simulated temperature at the measuring point and its deviation from the measured temperature. This allows one or more of the simulation models to be trained to minimize the deviation. In this way, the simulation models can be calibrated in test mode, during commissioning and/or at regular intervals during operation of the machine in order thus to increase the accuracy of the temperature determination.

BRIEF DESCRIPTION

Some of the embodiments will be described in detail, with reference to the following figures, wherein like designations denote like members, wherein:

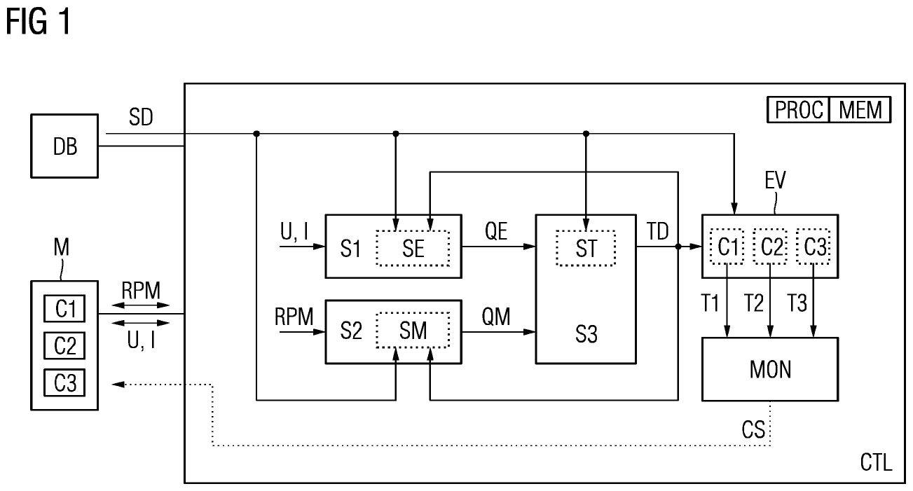

FIG. 1 shows monitoring the temperature of an electric motor by a motor controller according to embodiments of the invention; and

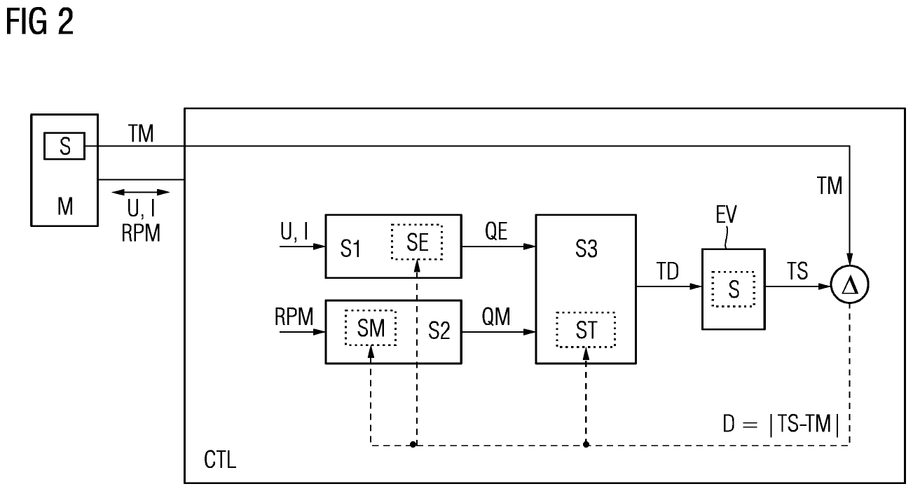

FIG. 2 shows calibration of a motor controller according to embodiments of the invention.

### DETAILED DESCRIPTION

FIG. 1 shows monitoring the temperature of an electric motor M in the form of an electromechanical machine by a motor controller CTL according to embodiments of the invention in the form of a machine controller according to embodiments of the invention. Alternatively, the electromechanical machine M to be monitored can also be a robot, a machine tool, a turbine, a production machine, a motor vehicle, a 3D printer or a component thereof or comprise such machines or components. The motor controller CTL can in particular comprise an inverter.

In addition, the motor controller CTL has one or more processors PROC for executing a method according to embodiments of the invention and one or more memories MEM for storing data to be processed.

In FIG. 1, the machine controller CTL is shown externally to the electromechanical machine M and coupled to it. Alternatively, the machine controller CTL can also be fully or partially integrated into the electromechanical machine M.

The motor controller CTL is used to operate and control the electric motor M. For this purpose, the motor controller CTL can, in particular, specify a motor speed RPM for the electric motor M and/or supply the electric motor M with a corresponding operating voltage U and/or a corresponding operating current I. In particular, the electric motor M can be powered by an inverter (not shown) of the motor controller CTL. In addition, the motor controller CTL can detect currently measured motor speeds RPM, operating voltages U and/or operating currents I from sensors of the electric motor M. For reasons of clarity, measured and predetermined operating data are each designated by the same reference sign in the figures.

Alternatively or in addition to the motor speeds RPM, further mechanical operating data of the electromechanical machine M can be recorded or used by the machine controller CTL, for example a torque, a speed of movement and/or an exerted force of the machine M or of a component thereof. Accordingly, in addition to the operating voltages U or the operating currents I, further current electrical operating data of the electromechanical machine M or of a component thereof can be recorded or used by the machine controller CTL.

For the present exemplary embodiment, it is assumed that the machine M has three machine components C1, C2 and C3 whose temperature is to be monitored on a component-specific basis. In the case of an electric motor, a respective machine component to be monitored can in particular be a rotor, a stator, a winding, an axle bearing or an insulation of the electric motor.

The machine controller CTL is furthermore coupled to a database DB in which structural data SD on a geometry, a thermal conductivity and an electrical conductivity of elements of the machine M are stored. Thermal conductivity can be equivalently expressed or represented by a thermal resistance, and an electrical conductivity by an electrical resistance.

In addition, the structural data SD comprise friction coefficients for elements of the machine M affected by friction losses. In particular, these can be friction coefficients for friction between a rotor axle and an axle bearing.

Examples of the machine elements described by the structural data SD are in particular the machine components C1, C2 and C3 or parts thereof as well as parts of the machine M with a specific influence on electrical conduction, thermal conduction and/or friction during operation of the machine M. These can be, for example, coatings, electrical lines, switching elements, thermal bridges or other structural elements of the machine M. The structural data SD specify the thermal conductivity, electrical conductivity and/or friction, in spatially resolved form.

The machine controller CTL comprises a first simulation module S1 with an electrical simulation model SE of the machine M, a second simulation module S2 with a mechanical simulation model SM of the machine M and a third simulation module S3 with a thermal simulation model ST of the machine M.

The first simulation module S1 is used to continuously simulate electrical energy losses QE in the machine M in a spatially resolved and time-resolved manner using the electrical simulation model SE. The second simulation module S2 is used to continuously simulate mechanical energy losses QM in the machine M in a spatially resolved and time-resolved manner using the mechanical simulation model SM. Finally, the third simulation module S3 is used to continuously simulate a temperature distribution TD in the machine M in a spatially resolved and time-resolved manner using the thermal simulation model ST. The electrical simulation model SE and the mechanical simulation model SM can be combined to form an electromechanical simulation model if necessary. The simulation modules S1, S2 and S3 each run a real-time simulation while the machine M is in operation.

To initialize the simulation models SE, SM and ST, the machine controller CTL feeds at least part of the imported structural data SD into the simulation modules S1, S2 and S3. As a result, the electrical simulation model SE is initialized by structural data SD on the geometry and electrical conductivity of machine elements. Similarly, the mechanical simulation model SM is initialized by structural data SD on the geometry and friction of machine elements. Finally, the thermal simulation model ST is initialized by structural data SD on the geometry and thermal conductivity of machine elements.

Many efficient methods and models for physical simulation are available for carrying out the above simulations. In particular, finite element methods or efficient surrogate models can be used for the simulation. A surrogate model is understood here in particular to be a method that is simplified or at least requires fewer computing resources than a detailed physical simulation and that reproduces the desired simulation results as accurately as possible. In particular, a neural network or another machine learning model that has been trained in advance using a detailed physical simulation model to predict its simulation results can be used as a surrogate model. After training, such a data-driven surrogate model can generally be evaluated considerably faster than the detailed physical simulation model and, in particular, operated in real time.

After initializing the simulation models SE, SM and ST, the described simulations can be executed in real time using the current operating data, in this case U, I and RPM of the machine M. For this purpose, the current electrical operating data, in this case the operating voltage U and the operating current I, are continuously fed into the first simulation module S1. The first simulation module S1 then uses the electrical operating data U and I to continuously simulate the electrical energy losses QE in the machine M in a spatially resolved and time-resolved manner using the initialized electrical simulation model SE. The simulated electrical energy losses QE are fed into the third simulation module S3 by the first simulation module S1.

Furthermore, the current mechanical operating data, in this case the current rotational speed RPM, are continuously fed into the second simulation module S2. The second simulation module S2 thus uses the mechanical operating data RPM to continuously simulate the mechanical energy losses QM in the machine M in a spatially resolved and time-resolved manner using the initialized mechanical simulation model SM. The simulated mechanical energy losses QM are fed into the third simulation module S3 by the second simulation module S2.

Finally, the third simulation module S3 uses the simulated energy losses QE and QM to continuously simulate the temperature distribution TD in the machine M in a spatially resolved and time-resolved manner using the initialized thermal simulation model ST.

The simulated temperature distribution TD can be fed back to the simulation models SE, SM and ST in order to modify the structural data SD on which the models SE, SM and ST are based. In this way, temperature-dependent electrical resistances can be taken into account in the electrical simulation model SE, temperature-dependent thermal resistances can be taken into account in the thermal simulation model ST and/or temperature-dependent mechanical properties of machine elements can be taken into account in the mechanical simulation model SM. In many cases, this can significantly increase the accuracy of the simulations.

The simulated temperature distribution TD is continuously fed into an evaluation module EV of the machine controller CTL by the third simulation module S3. To initialize the evaluation module EV, structural data SD on the geometry of the machine elements was transferred to the evaluation module EV in advance. In particular, the transmitted structural data SD indicate the spatial positions of the machine components C1, C2 and C3 in the machine M.

The evaluation module EV continuously evaluates the spatially resolved and time-resolved temperature distribution TD at a respective position of the machine components C1, C2 or C3. A respective component-specific temperature value T1, T2 or T3 is determined at the respective position of the respective machine component C1, C2 or C3.

The temperature values T1, T2 and T3 are transmitted from the evaluation module EV to a monitoring module MON of the machine controller CTL. The monitoring module MON uses the transmitted component-specific temperature values T1, T2 and T3 to continuously check whether a permissible maximum temperature of a respective component C1, C2 or C3 is exceeded and/or a respective target temperature is maintained. This can be done, for example, by comparison with predetermined threshold values and/or with predetermined temperature intervals.

Depending on these checks, the machine M can be regulated down by the monitoring module MON, a cooling device of the machine M can be activated and/or information or a recommendation for optimized operation of the machine M can be provided. A suitable control signal CS is generated by the monitoring module MON to control the machine M accordingly and—as indicated by a dotted arrow in FIG. 1—transmitted to the machine M.

Embodiments of the invention allow efficient and precise temperature monitoring of the machine or motor M using operating data that are currently measured or specified by the machine controller CTL, in this case U, I, RPM, which are already available in many machine controllers, motor controllers or inverters. In this way, temperature monitoring can be implemented so that in many cases does not require complex sensors to be installed on or in the motor.

FIG. 2 illustrates a calibration of the motor controller CTL by calibrating its simulation models SE, SM and/or ST. Insofar as the same or corresponding reference signs are used in FIG. 2 as in FIG. 1, these reference signs designate the same or corresponding entities, which can be implemented or designed in particular as described above. Some of the components and data flows of the machine controller CTL and the machine M shown in FIG. 1 are no longer explicitly shown in FIG. 2 for reasons of clarity.

To calibrate a respective simulation model SE, SM or ST, a temperature TM measured by a temperature sensor S of the machine M is recorded by the machine controller CTL. The temperature sensor S is attached to an easily accessible measuring point on the outside of the machine controller CTL. The measured temperature TM therefore reflects the temperature of the machine M at the measuring point.

Furthermore, as described above, the machine controller CTL simulates a temperature distribution TD using the specified structural data SD and the current operating data U, I and RPM by means of the simulation modules S1, S2 and S3 and transmits this to the evaluation module EV. The latter evaluates the temperature distribution TD at the position of the sensor S specified by the structural data SD and thus determines a simulated temperature TS at the measuring point. In addition, a deviation D between the simulated temperature TS and the measured temperature TM is determined, for example as the absolute value or square of a difference TS-TM. The deviation D is fed back to the simulation models SE, SM and/or ST—as indicated by the dotted arrows in FIG. 2—in order to train them to minimize the deviation D. Training is understood here to mean modifying simulation parameters of the relevant simulation models SE, SM or ST in such a way that the resulting deviations D are minimized. A large number of efficient optimization methods, especially machine learning methods, are available for such minimization problems.

In many cases, this type of calibration can significantly increase the accuracy of temperature determination. Calibration can be carried out in particular during test operation, during commissioning or at regular intervals during ongoing operation of the machine M.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A computer-implemented method for monitoring the temperature of an electromechanical machine on the basis of electrical operating data of the machine, wherein
a) importing structural data on geometry, thermal conductivity and electrical conductivity of elements of the machine,
b) based on the structural data and the electrical operating data, continuously simulating electrical energy losses in the machine in a spatially resolved manner using an electrical simulation model of the machine,
c) based on the structural data and the simulated electrical energy losses, continuously simulating a temperature distribution in the machine using a thermal simulation model of the machine, and
d) according to the simulated temperature distribution, determining a temperature value for a component of the machine and output for monitoring the temperature thereof.

2. The method as claimed in claim 1, wherein mechanical energy losses in the machine are simulated in a spatially resolved manner using the structural data and mechanical operating data of the machine by means of a mechanical simulation model of the machine, and the simulation of the temperature distribution is carried out using the simulated mechanical energy losses.

3. The method as claimed in claim 1, wherein
a rotational speed, a torque, a speed of movement and/or an exerted force of the machine is quantified by the mechanical operating data.

4. The method as claimed in claim 1, wherein
an operating current and/or an operating voltage of the machine is quantified by the electrical operating data.

5. The method as claimed in claim 1, wherein
structural data on the electrical conductivity and/or the thermal conductivity of the machine elements are modified depending on the simulated temperature distribution, and
a simulation of the electrical energy losses and/or the temperature distribution is carried out using the modified structural data.

6. The method as claimed in claim 1, wherein
depending on the temperature value
the machine is regulated down,
information about optimized operation of the machine is output, and/or
a cooling device is activated.

7. The method as claimed in claim 1, wherein
at least one of the simulations is carried out using a data-driven surrogate model.

8. The method as claimed in claim 1, wherein
a position of a respective machine component is determined in each case for a plurality of predetermined machine components on the basis of the structural data, and
a component-specific temperature value is output based on the respectively determined position and the temperature distribution.

9. The method as claimed in claim 1, wherein
a temperature of the machine is measured at a measuring point,
the simulated temperature distribution is used to determine a simulated temperature at the measuring point and its deviation from the measured temperature, and
at least one of the simulation models is trained to minimize the deviation.

10. A machine controller for operating and monitoring the temperature of an electromechanical machine, configured for executing a method as claimed in claim 1.

11. A computer program product, comprising a computer readable hardware storage device having computer readable program code stored therein, said program code executable by a processor of a computer system to implement a method configured for executing the method as claimed in claim 1.

12. A computer-readable storage medium comprising the computer program product as claimed in claim 11.
